(19) United States
(12) Patent Application Publication
(10) Pub. No.: US 2022/0247343 A1
(43) Pub. Date: Aug. 4, 2022

(54) THERMOELECTRIC ACTIVE STORAGE EMBEDDED HYBRID SOLAR THERMAL AND PHOTOVOLTAIC WALL MODULE

(71) Applicant: Yonghua Wang, Klamath Falls, OR (US)

(72) Inventor: Yonghua Wang, Klamath Falls, OR (US)

(21) Appl. No.: 16/974,431

(22) Filed: Jan. 29, 2021

(51) Int. Cl. H02S 10/30; H02S 10/20; H02S 20/25; H02S 20/26; H02S 40/42; H01L 35/32

(52) U.S. Cl. CPC H02S 10/30; H02S 10/20; H01L 35/32; H02S 20/26; H02S 40/42; H02S 20/25

(57) ABSTRACT

Solar collection and storage module systems as building blocks are provided to build walls or shingles of buildings to transform any buildings into stabilized power generation stations and tie to power grid to form power grid-interactive efficient buildings. The solar collection and storage module system comprises a hybrid photovoltaic and thermal panel, thermoelectric modules, thermal storage package, control system, and battery storage. The incident sunlight is partially converted into electricity directly by the photovoltaic part of the system directly, and rest part is transformed into heat which is extracted, boosted to high temperature, and stored into the thermal storage package by the thermoelectric modules operating in cooler mode at this movement. At night or in cloudy days, the stored heat flow through the thermoelectric modules, which are switched to generator mode by the control system, generating electricity. In the module system, the cogenerated heat is stored in thermal energy format and outputted in electrical energy format; the total conversion efficiency of the module system is significantly improved. When the module systems are used as wall modules or shingles to build buildings, the encapsulation properties of the buildings are substantially improved.

### TECHNICAL FIELD

The present invention relates generally to solar collection, solar power generation and solar energy storage systems, more specifically, to hybrid solar thermal and photovoltaic module system with a thermal storage activated by thermoelectric devices to store thermal energy but release electric energy as building block of wall or shingle module.

### BACKGROUND

The Sun provides Earth with as much energy every hour as human civilization uses every year (O. Morton, 2006, “Silicon Valley Sunrise”, Nature, 443, Sep. 7, 2006). If a small fraction of those sun rays were captured and used in place of fossil fuels, there would be no need for power plants with environmentally disastrous greenhouse gas emissions. However, up to the present, the all of the installed solar equipments contribute less than 3.5% of the power supply over the world. The main reason for such a low contribution rate is the high cost, low efficiency and intermittence of solar energy technology. In order to make solar energy the main stream of power supply of the modern society, the three grand challenges from solar energy technology must be effectively addressed. In modern society, there are three major energy utilization sectors, power grid, building, and transportation. As Electric Vehicles (EVs) are widely adopted, the three major sectors are strongly coupled together. The bidirectional chargeable EVs may transport power between buildings and reversely charge power grid through buildings. Power grid may interact with buildings with energy storage. Among the three major energy sectors, building plays a central role to connect power grid, EVs and EV charging stations. Building also appears to be a perfect platform to integrate variety of technologies to address the three grand challenges of solar energy technology so as to enable the transition from fossil fuel to renewable energy.

Buildings occupy a large portion of the earth's surface and have a great potential to be large scale solar collectors. However, rather than contributing to the energy collection, buildings consume huge amount of energy due to solar radiation. In United States, building is responsible for 38% of carbon dioxide emission, 71% of electricity consumption, 39% of energy use, and 12% of water consumption. Efficient solar energy use in buildings will significantly impact the entire landscape of energy consumption and carbon dioxide emission. Currently, the green building movement mainly focuses on increasing the efficiency of existing technologies, which is slowly progressing the efficiency and affordability of these technologies for homeowners. In fact, there is a more disruptive approach which is transforming conventional buildings into green buildings. In this approach, the buildings are directly transformed into stabilized power generation stations by deploying active building envelope elements, which not only reduce heat transfer to/from outside air, but also generate electric power and store thermal energy which is subsequently converted back into electricity when needed. Conventionally, photovoltaic panels are widely adopted as wall modules for façade of buildings or shingles for roof of buildings to transit buildings into power generation stations. However, photovoltaic panels cogenerate a great amount of heat that lowers photovoltaic conversion efficiency. Moreover, the power generation stations transited from buildings are not stable due to the intermittent nature of the solar radiation resource, which generates perturbation to power grid when interact with power grid. Conventional battery is prohibitively expensive for utility scale storage and appears not to be effective in dealing with the thermal energy management and improving the electric conversion efficiency of photovoltaic panels. The integration of thermoelectric modules, which demonstrate the capabilities to convert thermal energy into electricity and cool down the photovoltaic panels to improve their performance, to photovoltaic modules presents a great potential to form hybrid photovoltaic and thermoelectric modules with thermal storage as wall modules for façade of buildings or shingles for roof of buildings to realize stabilized efficient power generation stations. Replacing the encapsulation structure of buildings with the integrated solar collection and storage modules enables the grid-interactive efficient buildings. The energy demand for heating and cooling of buildings comes from the heat transfer through the walls and roof of the building encapsulation structures. The adoption of the integrated solar collection and storage modules as the wall and roof modules not only terminates the heat transfer through the wall and roof of buildings to tremendously improve its encapsulation property, but also transits the wall and roof into solar collection and storage components to generate and store electric power. By tying to power grid and through the interaction with power grid, the grid-interactive efficient buildings are able to support power grid to realize full renewable energy powered power grid and store the surplus power of power grid to improve the power grid efficiency, reliability and stability.

The prior arts on hybrid photovoltaic and thermoelectric modules mainly aim to boost the photovoltaic conversion efficiency by deploying the thermoelectric apparatus to further convert the dissipated heat from the photovoltaic conversion process into electricity. U.S. Pat. No. 8,420,926 B1 granted to Robert Martin Reedy (Reedy) et al, disclosed an invention to improve the photovoltaic performance by deploying thermoelectric module either as generator or cooler in different operation modes. Although the concept was approved effective in significantly improving the electric conversion efficiency of the integrated module, it does not include the means to address the issue of energy storage. Furthermore, it does not provide the method, apparatus and system to integrate the modules into buildings to transit the buildings into stabilized power generation stations.

As a compact building block, the hybrid photovoltaic and thermoelectric modules with heat transfer circulation systems can be deployed to construct or retrofit the encapsulation structure of new buildings or existing buildings. Armando C. Oliveira (Oliveira) (Armando C. Oliveira, A novel solar facade concept for energy polygeneration in buildings, International Journal of Low-Carbon Technologies Advance Access, Jul. 16, 2015) presents a novel façade concept of wall module constructed by combining photovoltaic panel, solar air collector, and thermoelectric module as heat pump as an envelope solution of building. Although this solution is demonstrated effective in improving the encapsulation properties, it still does not include the energy storage function to address the issue of the intermittence of building power generation.

The objectives of the present invention are to: 1) present method, apparatus and system to dramatically improve the overall electric conversion efficiency of the hybrid photovoltaic and solar thermal module; 2) present method, apparatus and system to effectively address the intermittence issue of the hybrid photovoltaic and solar thermal module; 3) present method, apparatus and system for façade, roof and support structure of buildings as the solution of envelop to realize stabilized power generation stations; 4) use hybrid photovoltaic and thermoelectric modules with thermal storage to improve the encapsulation properties of building to save energy for heating and cooling; 5) transit whatever buildings into solar buildings without alternating their structure and functions; 6) maximize the overall energy conversion efficiency of the buildings through all four seasons without sacrificing the comfort of the occupants.

The present invention is to provide a design paradigm in which a hybrid photovoltaic and solar thermal panel is combined with a thermoelectric generator/cooler and a thermal storage package to form an electric power generation and storage module. When in operation, during the collection and conversion phase, portion of the incident light is converted into electricity directly and the rest part is converted into heat, then the heat is pumped from low temperature to high temperature by using thermoelectric cooler and stored in the insulated thermal storage. At night or in cloudy days, the stored heat flow through the thermoelectric generator, which works in the thermoelectric cooler mode in the collection and conversion phase described above, to regenerate electric power. During the collection and conversion phase, the thermoelectric cooler not only raises the temperature of the cogenerated heat to increase the energy density of thermal storage and improve the conversion efficiency of the next phase, but also cools down the photovoltaic panel to increase its conversion efficiency. In conjunction with thermoelectric generator/cooler, the cogenerated heat is stored in thermal energy, but outputted in electric energy. When this type of module is used as building block to build the wall or shingle of building, the building will be transited into a solar building which collects and converts sunlight into electric power and thermal energy, as well as stores the thermal energy and releases it back to electricity. By using this type of modules as wall modules or shingles to build a building, the envelope of the building is dramatically improved and significant amount of energy for heating and cooling is saved. These modules can also be integrated into the building structures to save building materials. By coordinating the solar collection, conversion, and storage, the building integrated with this type of modules will be transited into a stabilized power generation station. The community of this type of power generation stations can support power grid to form a fully renewable energy powered power grid system.

The present invention is also to provide a core component of building the photovoltaic and solar thermal cogeneration wall module with thermal storage and thermoelectric modules to transform any type of building into a solar building without changing its structure and function. The wall modules comprise hybrid photovoltaic and solar thermal collectors, thermoelectric modules, thermal storage, and control systems. The collectors are hybrid Photovoltaic (PV) and Thermal (PVT) panels, and are cooled by the thermoelectric modules as coolers and the cogenerated heat by the PVT is stored in the thermal storage embedded with heat exchangers. The stored thermal energy is subsequently transformed back into electricity by the same set of thermoelectric modules as generators. A control system is added to coordinate the switching from generator mode to cooler mode.

As building blocks, the wall modules serve as energy collection/storage equipment and as part of the building's structure. The adoption of the hybrid PV and thermal panel as the solar collector for wall modules will raise the electric conversion efficiency from 15-20% to the total conversion efficiency about 72%. The addition of wall modules to a building will dramatically improve the envelope of the building through the shared thermal insulation of the solar collection system and the building structure. The system's electrical power output is balanced through alternation of PV power generation and thermal power generation.

The overall goal of the present invention is to provide a building block that cogenerates electricity and thermal energy and stores the generated thermal energy into the block via a thermoelectric heat pump, which boosts the temperature of the cogenerated thermal energy and cools down the photovoltaic portion of the building block, then the stored thermal energy is retrieved and turned back to electricity via the same set of thermoelectric module which serves as power generator at this movement. This strategy consequently provides a design paradigm of solar buildings and develops the corresponding solar energy collection and conversion equipment to realize ultra-high total energy conversion efficiency. This goal results in: distributed energy storage throughout the building body, substantial improvement of the building envelope, and ultra-high total electric power conversion efficiency.

### SUMMARY

According to the present invention, a hybrid photovoltaic and solar thermal module with thermal storage activated with thermoelectric modules is provided to dramatically increase the total conversion efficiency of solar system, and eventually realize stabilized power generation. In the structure of this type of modules, the hybrid photovoltaic and solar thermal panel is connected to the thermal storage component by thermoelectric modules. The thermoelectric modules switch its work modes between heat pump and generator. When in the collection and conversion phase during daytime, the thermoelectric modules extract heat from the backside of the hybrid photovoltaic panel transfer it to the thermal storage component, and raise the temperature of the heat during the heat transportation process. When in the discharging phase during night time or cloudy days, the stored heat is released out from the thermal storage component through the thermoelectric modules to generate electric power. This type of solar collection and storage modules synergistically combine hybrid photovoltaic and solar thermal cogeneration panel, thermoelectric modules, and thermal storage together to form a compact building block to tremendously improve the envelope of buildings. When the building blocks are used to construct the walls and roofs of buildings, the façade and top of buildings are converted into solar power generation station. In the mean time, due to the addition of the double insulation layers shared by the solar collection, conversion and storage modules and the buildings to the envelope of buildings, the properties of the building encapsulation are significantly improved.

Further aspects and advantages of the present invention will become apparent upon consideration of the following description thereof, reference being made of the following drawings.

### BRIEF DESCRIPTION OF THE DRAWINGS

The accompanying drawings, which are incorporated in and constitute a part of this specification, illustrate several embodiments of the invention and together with the description, serve to explain the principles of the invention.

FIG. 1 is the overview of the hybrid photovoltaic and solar thermal wall module package with thermoelectric activated thermal storage.

FIG. 2 is the profile section view of the hybrid photovoltaic and solar thermal wall module package with thermoelectric activated thermal storage.

FIG. 3 is the assembly of the photovoltaic panel and thermoelectric module.

FIG. 4 is the assembly of the heat exchanger embedded into the thermal mass packed into the insulation materials.

FIG. 5 is the block diagram indicating the connection of the components inside of the hybrid photovoltaic and solar thermal wall module package with thermoelectric activated thermal storage.

FIG. 6 is a schematic diagram indicating the installation of the hybrid photovoltaic and solar thermal packages with thermoelectric activated thermal storage into building as wall and shingle modules.

### DETAILED DESCRIPTION

Reference will now be made in detail to the present exemplary embodiments, examples of which are illustrated in the accompanying drawings. Wherever possible, the same reference numbers will be used throughout the drawings to refer to the same or like parts.

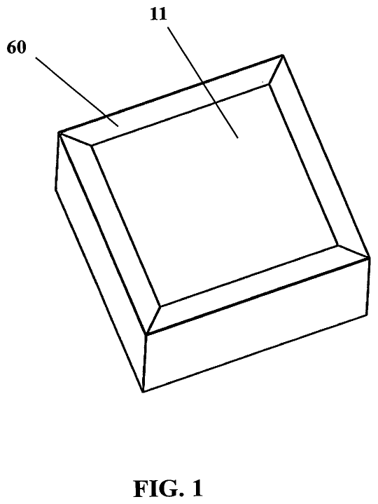

Referring to FIG. 1, the entire module is packed with frames 60, wherein the glazing 11 of the hybrid photovoltaic and thermal panel serves as the transparent cover of the module.

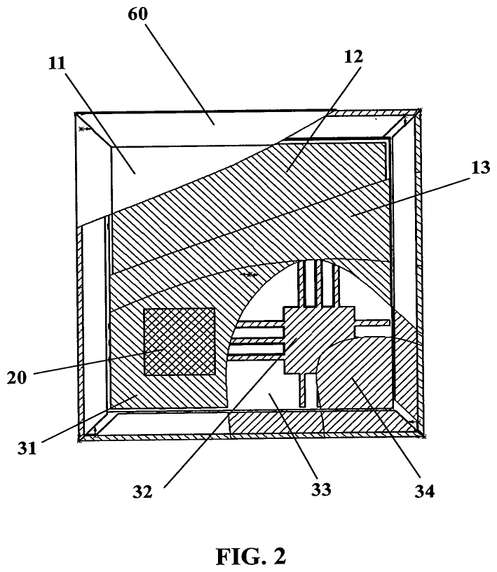

Referring to FIG. 2, the module consists of hybrid photovoltaic and thermal panel 10 which comprises the glazing 11, solar cell array 12, and the metal sheet 13, thermoelectric module 20, thermal storage package 30 which comprises the top insulation layer 31, heat exchanger 32, thermal mass 33, and backside insulation layer 34, and frames 60 with side insulation materials. The hybrid photovoltaic and thermal panel 10 is laminated and sealed; the thermoelectric modules 20 are attached to the backside of the metal sheet 13; the heat exchanger 32 is attached to the thermoelectric modules surrounded by the insulation layer 31; the heat exchanger 32 is buried into the thermal mass which is insulated by the back side insulation layer 34 and the side insulation materials within frames 60. When in operation, the incident sunlight penetrates through the glazing 11 and reaches the solar cell arrays 12; a portion of the sunlight is converted into electricity directly, and rest become heat; the heat is extracted, boosted its temperature, and transferred to the heat exchanger 32 by the thermoelectric modules 20; the heat exchanger 32 distributes the heat into the thermal mass 33. When at night or in cloudy days, the stored heat in the thermal mass 33 transferring through the heat exchanger 32 and the thermoelectric modules 20, is converted back into electricity by the thermoelectric modules 20 which is operating in the generator mode at this movement.

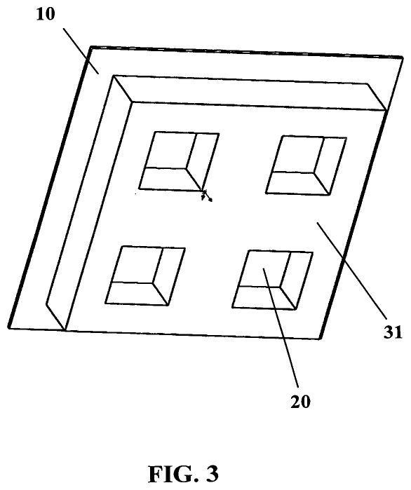

Referring to FIG. 3, the assembly of the hybrid photovoltaic and thermal panel 10, thermoelectric modules 20, and insulation layer 31, is further illustrated.

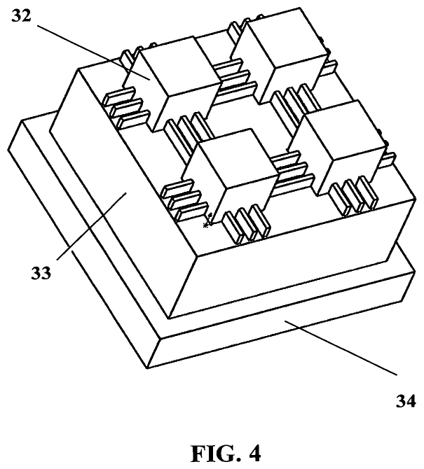

Referring to FIG. 4, the assembly of the heat exchanger 32, thermal mass 33 and the backside insulation layer 34 is further illustrated.

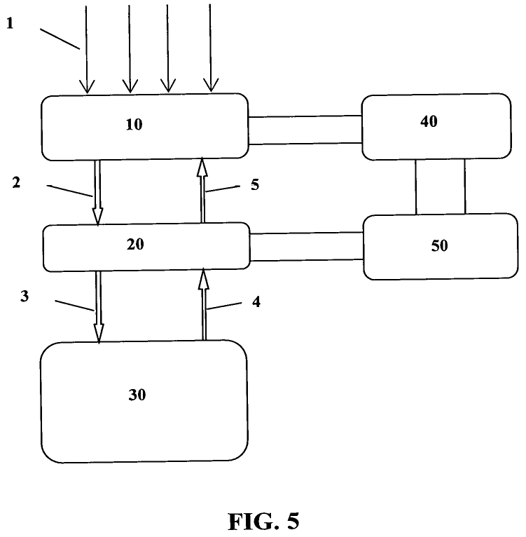

Referring to FIG. 5, the entire hybrid photovoltaic and thermal panel, thermoelectric module, and thermal storage module system comprise the hybrid photovoltaic and thermal panel 10, thermoelectric modules 20, thermal storage package 30, battery bank 40 and control system 50. When in operation, the sunlight 1 shines on the hybrid photovoltaic and thermal panel 10, which cogenerates electricity and heat, the cogenerated electricity is conducted to the battery bank 40, and the cogenerated heat 2 is transferred to thermoelectric modules and boosted up to higher temperature heat 3, then transferred into the thermal storage package 30. At night or in cloudy days, the stored heat 4 flow through the thermoelectric modules 20 to convert it back to electricity with control system 50 to switch the operating modes of the thermoelectric modules from cooler to generator, the heat 5 dissipated from the thermoelectric modules 20 is transferred back to the hybrid photovoltaic and thermal panel 10. The thermoelectric module generated electricity is conducted to battery bank 40 through the control system 50.

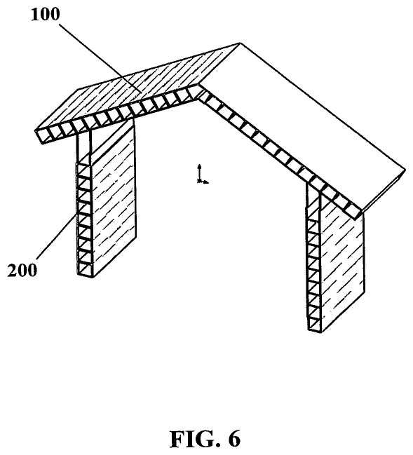

Referring to FIG. 6, the hybrid photovoltaic and thermal panel, thermoelectric module, and thermal storage package systems are integrated into the building roofs 100 as shingles and the walls 200 as wall modules to form the envelope of building.

From the description above, a number of advantages of the solar collection and storage module become evident. The solar collection and storage module not only generates both electrical energy and thermal energy to dramatically increase the total conversion efficiency of solar system, but also stores the generated thermal energy, this enables the whole building built with the solar collection and storage modules to be a large scale power generation and storage system. The storage of the solar collection and storage modules not only make the building body into a large scale energy storage, but also significantly improve the encapsulation properties of the building as the building shares the two layers of the insulation of the storage with the solar collection and storage modules. The solar collection and storage module's photovoltaic conversion efficiency is improved by the thermoelectric modules when they are working in the cooler mode, in the meantime, the cogenerated heat is boosted to high temperature by the thermoelectric modules, so that the heat is stored in the thermal mass at high temperature and the conversion efficiency of the thermoelectric modules is improved when they are working in the generator mode. The cogenerated heat is stored in thermal energy form but outputted in electric energy form. The solar collection and storage system forms a compact package with a control system to have potential to make the package a smart component of building.

I claim:

1. An solar collection and storage module system as building block comprises: a) a hybrid photovoltaic and thermal panel; b) thermoelectric modules; c) a thermal storage package with a buried heat exchanger; d) frames with insulation materials; e) a battery storage; f) a control system, wherein the thermoelectric modules contact on the backside of the hybrid photovoltaic and thermal panel, and the buried heat exchanger in the thermal storage package contact on the backside of the thermoelectric modules; the hybrid photovoltaic and thermal panel is connected to the battery storage with cables and the control system is connected to the thermoelectric modules and the battery storage with cables, when in operation, the incident sunlight on the hybrid photovoltaic and thermal panel is partially converted into electricity and partially into heat, the electricity is conducted to the battery for storage, and the heat is extracted, boosted to high temperature and transferred to the thermal storage package by the thermoelectric modules as coolers at this movement, when at night or in cloudy days, the stored heat in the thermal storage package flow out through the thermoelectric modules which is switched to the generator mode by the control system to generate electricity.

2. The hybrid photovoltaic and thermal panel of claim 1, comprises a transparent glazing, a solar cell array, a metal sheet, which are laminated and sealed.

3. The thermoelectric modules of claim 1, contact the backside of the metal sheet of claim 2 with their front sides.

4. The thermal storage package of claim 1, comprises a front insulation layer, a heat exchanger, thermal mass, and backside insulation layer.

5. The heat exchanger of claim 4, contacts to the backsides of the thermoelectric modules of claim 3.

6. The frames of claim 1, pack the hybrid photovoltaic and thermal panel of claim 2, the thermoelectric modules of claim 3, and the thermal package of claim 3 together and provide the side insulation layers.

7. The control system of claim 1, swatches the thermoelectric modules from cooler mode to generator mode.

8. The solar collection and storage module systems of claim 1, are used as wall modules to construct walls, and shingles to construct roofs of buildings.
